(19) United States
(12) Patent Application Publication
(10) Pub. No.: US 2015/0346294 A1
(43) Pub. Date: Dec. 3, 2015

(54) MAGNETIC RESONANCE IMAGING DEVICE

(71) Applicants: KABUSHIKI KAISHA TOSHIBA, Tokyo (JP); TOSHIBA MEDICAL SYSTEMS CORPORATION, Otawara-shi (JP)

(72) Inventors: Kazuto NOGAMI, Nasushiobara (JP); Yoshitomo SAKAKURA, Nasushiobara (JP); Hidekazu TANAKA, Otawara (JP)

(21) Appl. No.: 14/823,354

(22) Filed: Aug. 11, 2015

Related U.S. Application Data
(63) Continuation of application No. PCT/JP2014/060758, filed on Apr. 15, 2014.

(30) Foreign Application Priority Data
Apr. 15, 2013 (JP) 2013-085244

(51) Int. Cl. G01R 33/34

(52) U.S. Cl. CPC G01R 33/34

(57) ABSTRACT

A magnetic resonance imaging device according to embodiments includes a substantially cylindrical-shaped coil structure. The coil structure includes a static field magnet generating a magnetostatic field in a space inside a cylinder, and a gradient coil disposed inside the cylinder of the static field magnet and generating a gradient magnetic field. In the coil structure, magnetic bodies are supported independently of the gradient coil, and are disposed near the center of the coil structure in the long axis direction in such a way as to extend along the circumferential direction of the substantially cylindrical shape.

### CROSS-REFERENCE TO RELATED APPLICATIONS

This application is a continuation of PCT international application Ser. No. PCT/JP2014/060758 filed on Apr. 15, 2014 which designates the United States, incorporated herein by reference, and which claims the benefit of priority from Japanese Patent Application No. 2013-085244, filed on Apr. 15, 2013, the entire contents of which are incorporated herein by reference.

### FIELD

Embodiments described herein relate generally to a magnetic resonance imaging device.

### BACKGROUND

Magnetic resonance imaging is an imaging method for magnetically exciting nuclear spins of a subject set in a magnetostatic field with a radio frequency (RF) pulse of the Larmor frequency thereof and generating an image from data of magnetic resonance signals generated due to the excitation.

Because this magnetic resonance imaging requires uniformity of a magnetic field, shimming for correcting non-uniformity (non-homogeneity) of the magnetic field is performed. This shimming includes passive shimming and active shimming. The passive shimming has been conventionally performed by disposing iron shims in a layer between a main coil and a shield coil in an active shield gradient coil (ASGC). There has been developed a method for disposing iron pieces and the like on an end surface and the like of a static field magnet and disposing iron shims in a gradient coil in order to reduce the amount of the iron shims.

A gradient coil may be moved from an original position by receiving an electromagnetic force because iron shims are disposed in the gradient coil as described above. Along this movement, uniformity of a magnetic field is deteriorated.

### BRIEF DESCRIPTION OF THE DRAWINGS

FIG. 1 is a functional block view illustrating the configuration of a magnetic resonance imaging (MRI) device according to a first embodiment;

FIG. 2 is a view illustrating the definition of terms in the embodiments;

FIG. 3 is a view illustrating the movement of a gradient coil;

FIG. 4 is a cross-sectional view of a coil structure where compensation members are disposed according to the first embodiment;

FIG. 5 is a view illustrating the disposition of substantially ring-shaped compensation members according to the first embodiment;

FIG. 6 is a view illustrating the disposition of the substantially ring-shaped compensation members according to the first embodiment;

FIG. 7 is a view illustrating the relation between positions where the compensation members are disposed, thickness of the compensation members, and generating z⁴ components;

FIG. 8 is a view illustrating another example of substantially ring-shaped compensation members according to the first embodiment;

FIG. 9 is a view illustrating the operation for adjusting a magnetic field according to the first embodiment;

FIGS. 10A and 10B are a view illustrating the comparison of distributions of the magnetic field uniformity in the case where compensation members are not disposed and in the case where the compensation members are disposed;

FIG. 11 is a view illustrating the disposition of the compensation members according to other embodiments;

FIG. 12 is a view illustrating the disposition of the compensation members according to other embodiments;

FIG. 13 is a view illustrating the disposition of the compensation members according to other embodiments; and

FIG. 14 is a view illustrating the disposition of the compensation members according to other embodiments.

### DETAILED DESCRIPTION

A magnetic resonance imaging device according to embodiments includes a substantially cylindrical-shaped coil structure. The coil structure includes a static field magnet generating a magnetostatic field in a space inside a cylinder, and a gradient coil disposed inside the cylinder of the static field magnet and generating a gradient magnetic field. In the coil structure, magnetic bodies are supported independently of the gradient coil, and are disposed near the center of the coil structure in the long axis direction in such a way as to extend along the circumferential direction of the substantially cylindrical shape.

A magnetic resonance imaging (MRI) device (hereinafter, appropriately referred to as an “MRI device”) according to embodiments will now be described with reference to the accompanying drawings. It should be noted that embodiments are not limited to the embodiments described below. In principle, the contents described in each of the embodiments can be applied to other embodiments in the same manner.

### First Embodiment

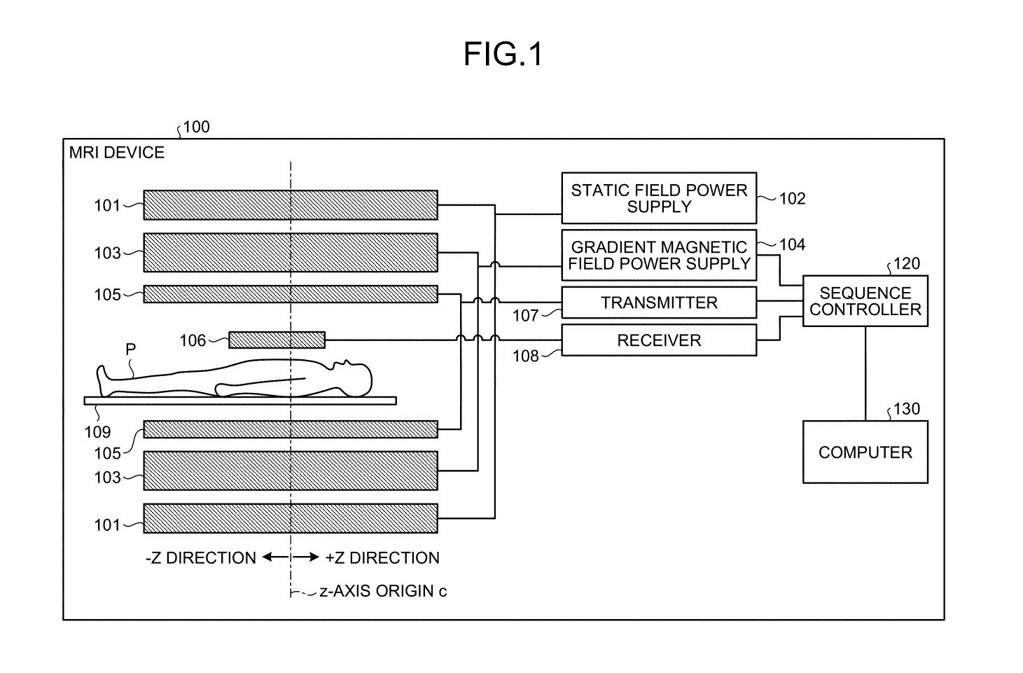

FIG. 1 is a functional block view illustrating the configuration of an MRI device 100 according to a first embodiment. As illustrated in FIG. 1, the MRI device 100 includes a static field magnet 101, a magnetostatic field power supply 102, a gradient coil 103, a gradient magnetic field power supply 104, a transmission coil 105, a reception coil 106, a transmitter 107, a receiver 108, a couch 109, a sequence controller 120, and a computer 130. A substantially cylindrical-shaped structure in which the static field magnet 101, the gradient coil 103, and the transmission coil 105 are laminated and supported is appropriately referred to as a “coil structure”. The MRI device 100 includes no subject P (for example, a human body). The configuration illustrated in FIG. 1 is merely one example. Each of the units may be integrated or separated as appropriate.

The static field magnet 101 is a magnet formed in a hollow and substantially cylindrical shape, and generates a magnetostatic field in a space inside the cylinder. The static field magnet 101 is, for example, a superconductive magnet and the like, and receives current from the magnetostatic field power supply 102 so as to be excited. The magnetostatic field power supply 102 supplies current to the static field magnet 101. The static field magnet 101 may be a permanent magnet. In this case, the MRI device 100 may include no magnetostatic field power supply 102. The magnetostatic field power supply 102 may be provided separately from the MRI device 100.

The gradient coil 103 is disposed inside the cylinder of the static field magnet 101, and is a coil formed in a hollow and substantially cylindrical shape. The gradient coil 103 receives current from the gradient magnetic field power supply 104 so as to generate a gradient magnetic field. The gradient magnetic field power supply 104 supplies current to the gradient coil 103.

The transmission coil 105 is disposed inside the cylinder of the gradient coil 103, and is a coil formed in a hollow and substantially cylindrical shape. The transmission coil 105 receives a radio frequency (RF) pulse from the transmitter 107 so as to generate a high frequency magnetic field. The reception coil 106 receives a magnetic resonance (MR) signal (hereinafter, appropriately referred to as an “MR signal”) generated from the subject P due to the influence of a high frequency magnetic field, and outputs the received MR signal to the receiver 108.

The transmission coil 105 and the reception coil 106 described above are merely examples. These radio frequency (RF) coils may be configured by combining one of or more of a coil having a transmission function, a coil having a reception function, and a coil having transmission and reception functions.

The transmitter 107 supplies an RF pulse corresponding to the Larmor frequency determined by the kind of a target atom and magnetic field intensity to the transmission coil 105. The receiver 108 detects an MR signal output from the reception coil 106, and generates magnetic resonance (MR) data based on the detected MR signal. Specifically, the receiver 108 digitally converts the MR signal output from the reception coil 106 so as to generate the MR data. The receiver 108 transmits the generated MR data to the sequence controller 120. The receiver 108 may be provided on a gantry side including the static field magnet 101 and the gradient coil 103.

The couch 109 includes a couchtop on which the subject P is loaded. FIG. 1 illustrates only this couchtop for convenience of explanation. The couch 109 is usually disposed such that the center axis of the cylinder of the static field magnet 101 and the longitudinal direction of the couch 109 are parallel to each other. The couchtop is movable in the longitudinal direction and the vertical direction, and is inserted into a space inside the cylinder of the transmission coil 105 while having the subject P loaded thereon.

The sequence controller 120 drives the gradient magnetic field power supply 104, the transmitter 107, and the receiver 108 to image the subject P based on sequence information transmitted from the computer 130. The sequence information defines a procedure for performing the imaging. The sequence information defines intensity of current supplied from the gradient magnetic field power supply 104 to the gradient coil 103 and a timing when the current is supplied, intensity of the RF pulse supplied from the transmitter 107 to the transmission coil 105 and a timing when the RF pulse is applied, a timing when the receiver 108 detects the MR signal, and the like.

Examples of the sequence controller 120 include integrated circuits such as an application specific integrated circuit (ASIC) and a field programmable gate array (FPGA), and electronic circuits such as a central processing unit (CPU) and a micro processing unit (MPU).

After the sequence controller 120 drives the gradient magnetic field power supply 104, the transmitter 107, and the receiver 108 to image the subject P, the sequence controller 120 receives the MR data from the receiver 108, and transfers the received MR data to the computer 130.

The computer 130 controls the whole MRI device 100. The computer 130 applies reconstruction processing such as the Fourier transform to the MR data transferred from the sequence controller 120 so as to generate a magnetic resonance (MR) image. For example, the computer 130 includes a controller, storage, an input unit, and a display. Examples of the controller include integrated circuits such as an ASIC and an FPGA, and electronic circuits such as a CPU and an MPU. Examples of the storage include semiconductor memory elements such as random access memory (RAM) and flash memory, a hard disk, and an optical disk. Examples of the input unit include pointing devices such as a mouse and a trackball, and input devices such as a keyboard. Examples of the display include display devices such as a liquid crystal display.

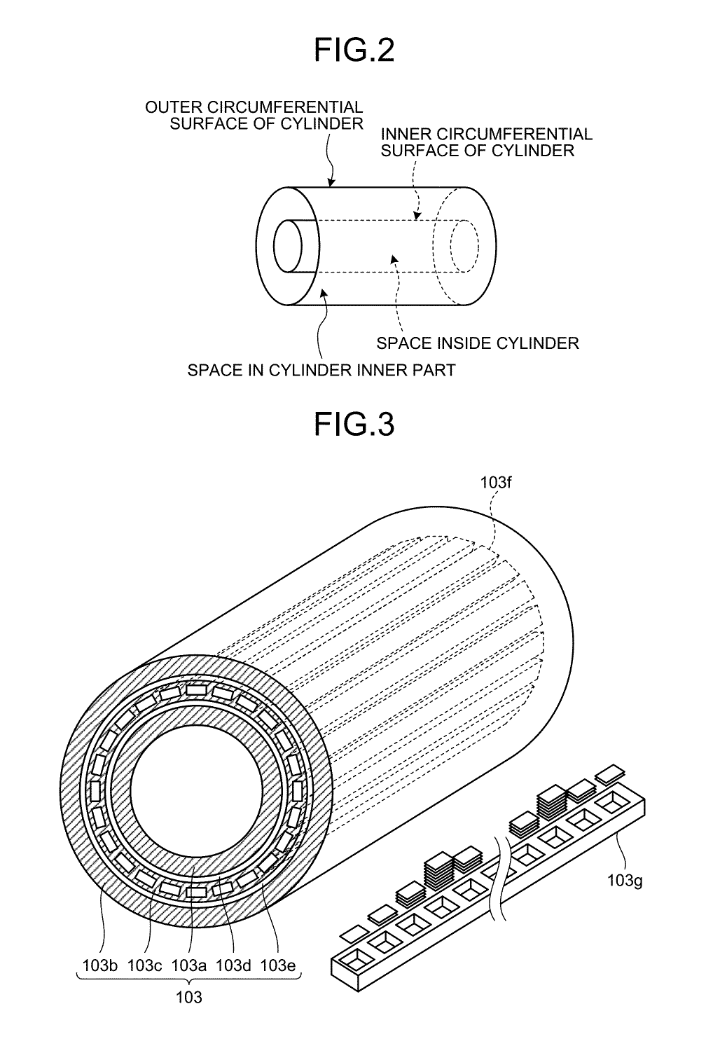

FIG. 2 is a view illustrating the definition of terms in the embodiments. In the following embodiments, a cylinder having thickness is assumed as illustrated in FIG. 2. A surface forming the outside of the cylinder is referred to as an “outer circumferential surface of the cylinder” and a surface forming the inside of the cylinder is referred to as an “inner circumferential surface of the cylinder”. A space surrounded by the inner circumferential surface of the cylinder is referred to as a “space inside the cylinder”, and a space in a thickness part of the cylinder is referred to as a “space in the cylinder inner part”. These names are defined merely for convenience of explanation. In the first embodiment, a substantially cylindrical shape may be a cylindrical shape having a perfect-circle cross section perpendicular to the center axis of a cylinder, and may be a cylindrical shape having an ellipse cross section. The shape of an ellipse indicates a shape of a perfect circle distorted without greatly impairing functions of the MRI device 100.

The following introduces a method for reducing distortion (deterioration) in uniformity of a magnetic field by appropriately disposing “compensation members” for compensating non-uniformity of the magnetic field. Non-uniformity components of a magnetic field to be reduced are magnetic field components generated by displacing the relative position of iron shims disposed in a space in the cylinder inner part of the gradient coil 103 along the movement of the gradient coil 103.

Non-uniformity components of a magnetic field formed by the static field magnet 101 can be represented by Expressions 1 and 2 in which a magnetic field component in the z direction (the center axis direction of the static field magnet 101, see FIG. 1) is expanded for each order.

$$\begin{matrix}B ( z ) = {\sum }_{n = 0}^{∞} {α}_{n} {P}_{n} ( z ) & ( 1 ) \\ B ( z ) = {α}_{1} {P}_{1} ( z ) + {α}_{2} {P}_{2} ( z ) + {α}_{3} {P}_{3} ( z ) + {α}_{4} {P}_{4} ( z ) + … & ( 2 )\end{matrix}$$

Terms up to a fourth-order term to which attention is paid this time can be specifically represented as below.

P₀(Z)=1, P₁(z)=z, P₂(z)=(3z²−1)/2, P₃(z)=(5z³−3z)/2, P₄(z)=(35z⁴−30z²+3)/8

Hereinafter, P₁(z) is referred to as a z¹ component, P₂(z) as a z² component, P₃(z) as a z³ component, and P₄(z) as a z⁴ component. Expression 2 omits higher-order components of a fifth-order term or higher.

Iron shims are disposed in a space in the cylinder inner part of the gradient coil 103 so as to form a magnetic field that cancels non-uniformity components in Expression 1. Expression 1 is determined in designing the static field magnet 101 so as to preliminarily calculate the disposed position and the amount of iron shims for forming a magnetic field that cancels non-uniformity components through simulation.

Methods for designing the static field magnet 101 include a design method A for designing the static field magnet 101 having high uniformity of a magnetic field and finely adjusting only an error component generated in terms of manufacturing accuracy with iron shims, and a design method B for designing the static field magnet 101 so that non-uniformity components are intentionally generated based on the use of iron shims and adjusting the non-uniformity components with the iron shims. In the method A, manufacturing costs tend to be high because of an increase in the number of modules of a superconductive coil and in adjustment man-hours, and the like. In the method B, manufacturing costs can be reduced, but a magnetic field component generated by displacing the relative position of iron shims due to heavy use of the iron shims can no longer be canceled by the iron shims, thereby greatly deteriorating the uniformity of a magnetic field.

FIG. 3 is a perspective view illustrating the configuration of the gradient coil 103 according to the first embodiment, and is a view illustrating the movement of the gradient coil 103. As illustrated in FIG. 3, the gradient coil 103 has a main coil 103a, a cooling layer 103d where a cooling pipe is laid, a shim layer 103c where iron shims are disposed, a cooling layer 103e where a cooling pipe is laid, and a shield coil 103b laminated in this order from the inside of the cylinder. In the shim layer 103c, a plurality of (for example, twenty-four) shim tray insertion guides 103f are formed, and a shim tray 103g is inserted into each of the shim tray insertion guides 103f. The shim tray 103g includes a plurality of (for example, fifteen) pockets in the longitudinal direction, and an iron shim is stored in each of the pockets as appropriate.

The gradient coil 103 is supported with cushioning members such as rubber and springs in order to absorb vibration during imaging. Iron shims disposed in a space in the cylinder inner part of the gradient coil 103 are not always disposed symmetrically with respect to the z-axis origin c, and may receive a large electromagnetic force in one direction. Accordingly, an iron shim in each of the pockets, the shim trays 103g, and the gradient coil 103 are moved, and the relative position of iron shims is displayed.

In this manner, when the relative position of iron shims is displayed, a new magnetic field component lowering an order by one level appears as a non-uniformity component of a magnetic field. For example, the z² component appears as the z¹ component, and the z⁴ component appears as the z³ component. In the z components, the z¹ component can be separately corrected using methods such as the active shimming for causing correction current to flow, but the z³ component cannot be corrected using such methods.

The first embodiment introduces a method for reducing non-uniformity components of a magnetic field generated by displacing the relative position of iron shims, mainly the z³ component, so as to reduce distortion in the uniformity of the magnetic field even when the static field magnet 101 is manufactured at a relatively low cost using not only the design method A but also the design method B. Specifically, reducing the z³ component generated after the displacement of the relative position of iron shims requires the z⁴ component generated by the iron shims before the displacement of the relative position of the iron shims to be reduced in the first place. In order to do this, an absolute value of the z⁴ component of the static field magnet 101 needs to be reduced. In the first embodiment, this operation is achieved by not the design method A but disposing the “compensation members” as appropriate.

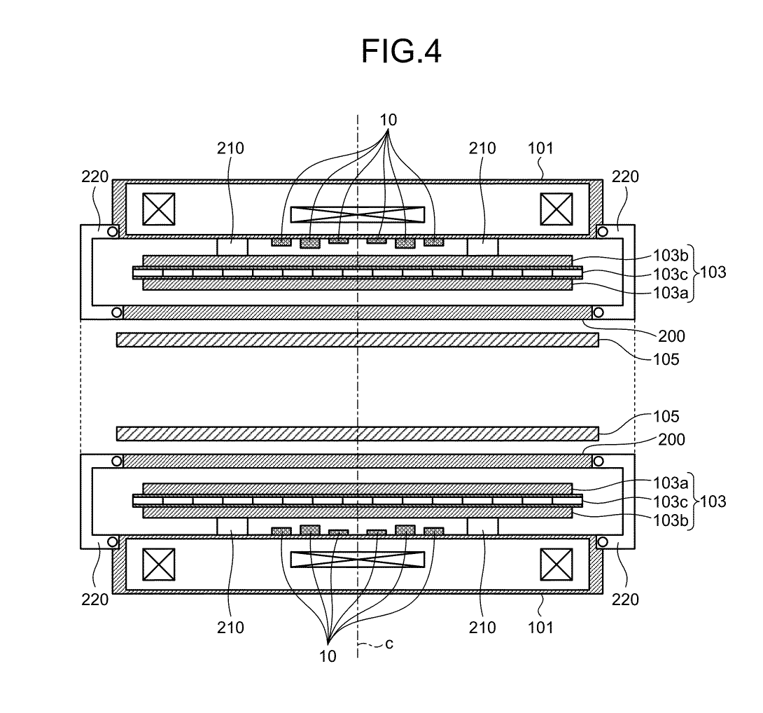

FIG. 4 is a cross-sectional view of the coil structure where the compensation members are disposed according to the first embodiment. As illustrated in FIG. 4, the coil structure is configured by laminating the substantially cylindrical-shaped static field magnet 101, the substantially cylindrical-shaped gradient coil 103, and the substantially cylindrical-shaped transmission coil 105. Both end parts of the static field magnet 101 and a bore tube 200 are fixed by end plates 220, and a space surrounded by the inner circumferential surface of the cylinder of the static field magnet 101 and the outer circumferential surface of the cylinder of the bore tube 200 is formed as a sealed container. The gradient coil 103 is supported in the sealed container by support units 210. Air in the sealed container is discharged by an unillustrated vacuum pump so as to form a vacuum space around the gradient coil 103. FIG. 4 does not illustrate the cooling layer 103d or the cooling layer 103e of the gradient coil 103 for convenience of explanation.

The transmission coil 105 is disposed inside the cylinder of the bore tube 200. FIG. 4 illustrates no support units for supporting the transmission coil 105, no bore tube for forming a living space for the subject P, and the like. In FIG. 4, the dotted and dashed line c represents the z-axis origin that is a center point of the coil structure in the long axis direction. The right direction from this z-axis origin is a plus (+) z direction, and the left direction from the z-axis origin is a minus (−) z direction.

In this configuration according to the first embodiment, the compensation members are disposed on a component supported substantially independently of the gradient coil 103 and receiving no influence of the movement of the gradient coil 103 (or a component receiving, even when receiving influence, small influence), out of the coil structure. For example, as illustrated in FIG. 4, three each of a compensation members 10 formed by a magnetic body such as silicon steel and cobalt steel are disposed in a substantially ring shape at positions symmetrical to the z-axis origin c (positions symmetrical to the XY plane) on the inner circumferential surface of the cylinder of the static field magnet 101. The compensation members 10 may be referred to as a ring shim, a z⁴ shim ring, and the like because the compensation members 10 are disposed in a substantially ring shape.

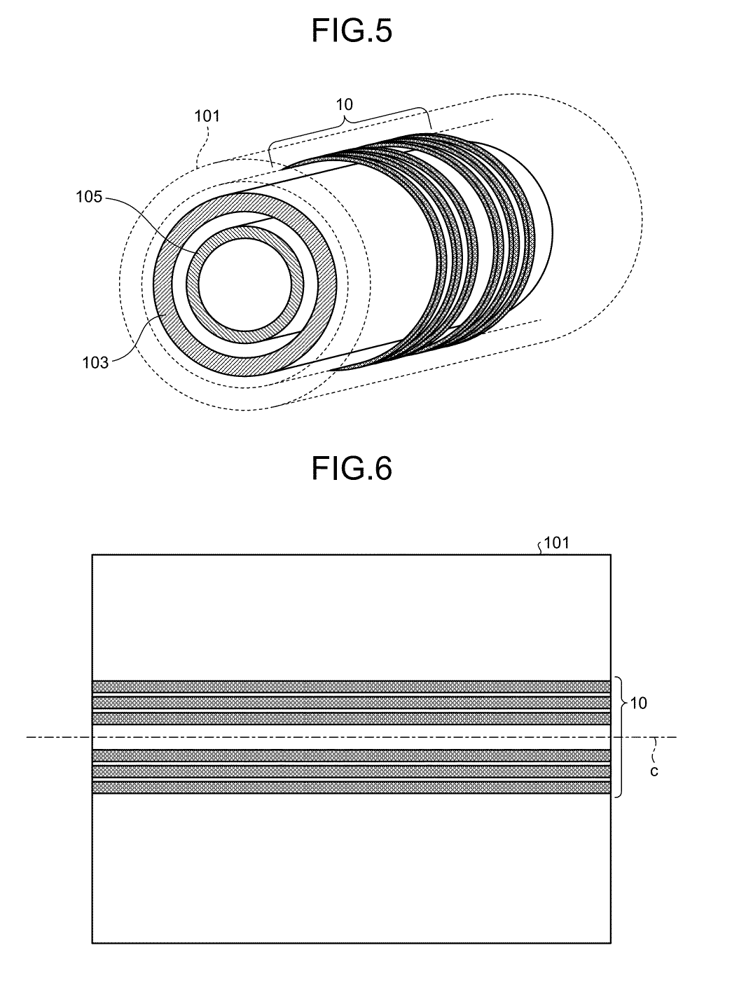

FIGS. 5 and 6 are views illustrating the disposition of the substantially ring-shaped compensation members 10 according to the first embodiment. FIG. 5 is a perspective view, and FIG. 6 is a development view of the inner circumferential surface of the cylinder of the static field magnet 101. For example, the compensation members 10 are disposed on the inner circumferential surface of the cylinder of the static field magnet 101 by welding and the like. Considering that an electromagnetic force is applied to the compensation members 10 after excitation, the inner circumferential surface desirably has a certain degree of strength.

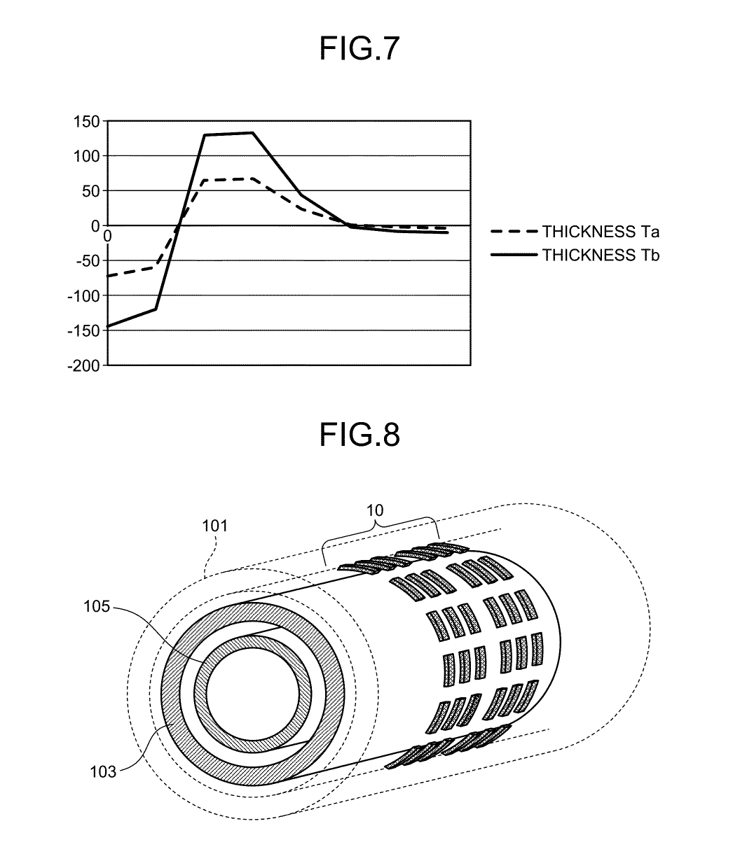

Referring back to FIG. 4, the substantially ring-shaped compensation members 10 have different thicknesses corresponding to the disposed position as illustrated in FIG. 4. To explain this point, FIG. 7 is a view illustrating the relation between positions where the compensation members 10 are disposed, thickness of the compensation members 10, and generating z⁴ components. In FIG. 7, a vertical axis represents magnetic field strength (ppm) and a horizontal axis represents a distance from the z-axis origin c. Two broken lines different in a line type represent two kinds of compensation members 10 different in thickness.

Thickness Ta is smaller than thickness Tb. The dotted and broken line represents, when the compensation member 10 having the thickness Ta is disposed at each position, an effect in which the compensation member 10 generates the z⁴ component. In other words, when the compensation member 10 having the thickness Ta is disposed at each position, the z⁴ component in a magnetic field generated by the static field magnet 101 is canceled and reduced by the z⁴ component illustrated in FIG. 7. The solid and broken line represents, when the compensation member 10 having the thickness Tb is disposed at each position, an effect in which the compensation member 10 generates the z⁴ component. Both of the compensation members 10 have low effect and little difference near the end part of the static field magnet 101, but the compensation member 10 having a larger thickness has a more remarkable effect near the z-axis origin c.

In this manner, the relation between positions where the compensation members 10 are disposed, thickness of the compensation members 10, and generating z⁴ components is a known relation by computation. Thus, the disposed position and thickness of the compensation member 10 may be determined as appropriate corresponding to an actually required z⁴ component. Specifically, the thickness of the compensation member 10 may be determined corresponding to a position in the z-axis direction and a position in the circumferential direction. In other words, the compensation member 10 may have different thicknesses depending on the disposed position.

The compensation members 10 are desirably disposed near the z-axis origin c (near the center of the coil structure in the long axis direction) because the compensation members 10 typically have a low effect near the end part as illustrated in FIG. 7. In addition, the compensation members 10 are desirably distributed and disposed at a plurality of positions as appropriate in order to reproduce the distribution of the z⁴ component more smoothly. If the z⁴ component of a magnetic field generated by the static field magnet 101 is symmetrical to the z-axis origin c, the compensation members 10 are desirably disposed symmetrically with respect to the z-axis origin c. As a result, FIGS. 4 to 6 illustrate examples where three each of the compensation members 10 having different thicknesses and substantially ring shapes are disposed at positions symmetrical to the z-axis origin c. When the thickness of the compensation member 10 is determined corresponding to the position in the circumferential direction, for example, the compensation member 10 having a larger thickness is disposed toward the lower side of the static field magnet 101 and the compensation member 10 having a smaller thickness is disposed toward the upper side of the static field magnet 101.

However, embodiments are not limited to this. As described above, the disposed position and thickness of the compensation member 10 may be determined as appropriate corresponding to an actually required z⁴ component. In other words, for example, the compensation members 10 may be disposed at the end part, and one, two, or four or more each of the compensation members 10 may be distributed and disposed. The compensation members 10 may have different thicknesses or may have the same thickness. The thickness and the position thereof may be asymmetrical to the z-axis origin c. The compensation members 10 may be distributed and disposed in a plurality of layers such as the outer circumferential surface of, the inner circumferential surface of, and a space in the inner part of the static field magnet 101, the bore tube 200, the transmission coil 105, and a bore tube forming a living space for the subject P.

FIG. 8 is a view illustrating another example of the substantially ring-shaped compensation members 10 according to the first embodiment. As illustrated in FIG. 8, the compensation members 10 are not necessarily a perfect ring, and may be a group of the compensation members 10 discretely forming a ring shape as illustrated in FIG. 8. If the compensation members 10 are formed in a perfect ring, eddy current could flow, and desirably, the compensation members 10 may be discretely formed in a ring shape.

The substantially ring-shaped compensation members 10 may be formed by laminating a plurality of thin plate-like materials. Each of the compensation members 10 disposed in the circumferential direction may have different thicknesses.

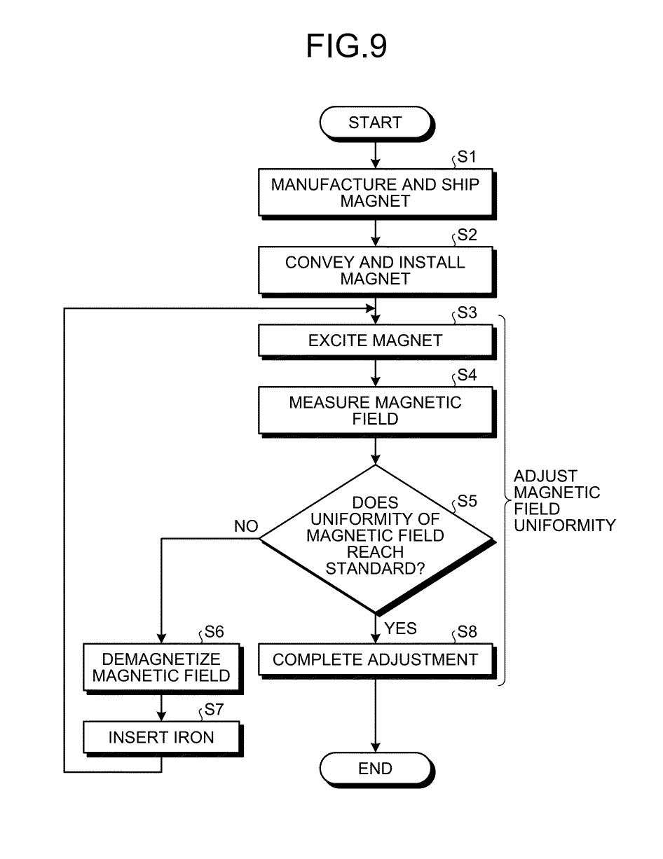

FIG. 9 is a view illustrating the operation for adjusting a magnetic field according to the first embodiment. The static field magnet 101 is manufactured and shipped (Step S1). The first embodiment uses a method in which the compensation members 10 are welded to the inner circumferential surface of the cylinder of the static field magnet 101, and the compensation members 10 are installed in this manufacturing stage.

The static field magnet 101 is conveyed into an installation place, and is assembled and installed as the MRI device 100 (Step S2). The static field magnet 101 receives current from the magnetostatic field power supply 102 so as to be excited (Step S3).

When the static field magnet 101 is excited, a magnetic field is measured using a field camera and the like (Step S4), and it is determined whether uniformity of the magnetic field reaches a standard (Step S5). If not (No at Step S5), the excited magnetic field is once demagnetized (Step S6), and the shim trays 103g are pulled out from the gradient coil 103, the disposed position and amount of an iron shim stored in each of the pockets is adjusted, the shim trays 103g are inserted again, and the like (Step S7).

If the uniformity of the magnetic field reaches a standard (Yes at Step S5), adjustment of the uniformity of the magnetic field is completed (Step S8).

In this manner, in the first embodiment, the compensation members 10 are disposed at the stage of manufacturing the static field magnet 101.

As described above, disposing the compensation members 10 can reduce the z⁴ component generated by the static field magnet 101. For example, if the above-mentioned compensation members 10 are disposed on the static field magnet 101 that has generated the z⁴ component of “−414 ppm” when no compensation members 10 are disposed, the z⁴ component can be reduced to “−184 ppm”. This operation reduces the z³ component generated by displacing the relative position of iron shims disposed in the cylinder inner part of the gradient coil 103. Specific numerical values are merely examples.

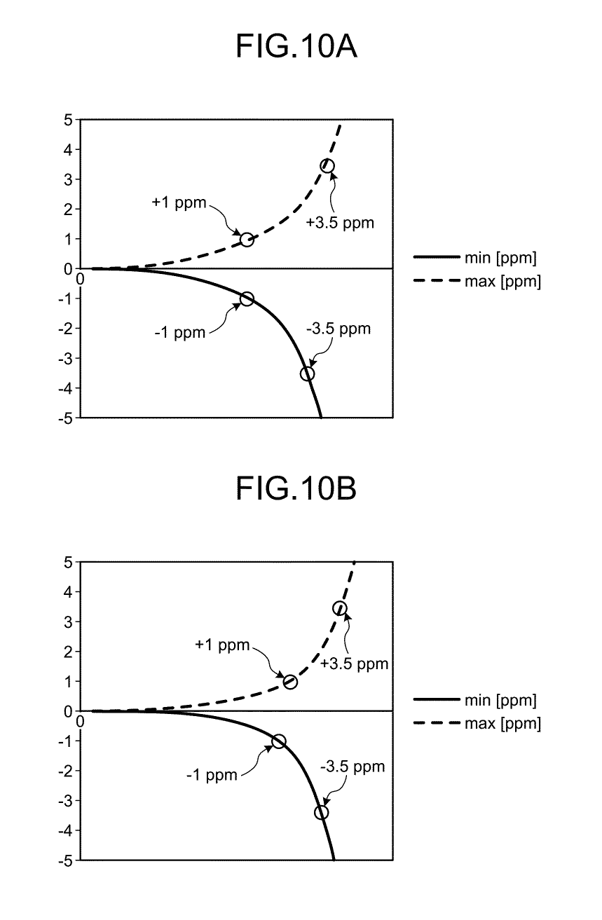

FIGS. 10A and 10B are views illustrating the comparison of distributions of the magnetic field uniformity in the case where compensation members 10 are not disposed and in the case where the compensation members 10 are disposed. FIG. 10A illustrates the case where compensation members 10 are not disposed, and FIG. 10B illustrates the case where the compensation members 10 are disposed. In FIGS. 10A and 10B, the case where the gradient coil 103 is moved by 1 mm is assumed.

In general, it is assumed that, when uniformity of a magnetic field exceeds about |1.0 ppm|, an imaging method for frequency-separating water and fat starts to be affected, and that, when uniformity of a magnetic field exceeds about |3.5 ppm|, water and fat cannot be frequency-separated. To address this, FIGS. 10A and 10B illustrate the comparison of positions of the radius in the z direction where the uniformity of a magnetic field corresponds to “+1.0 ppm”, “−1.0 ppm”, “+3.5 ppm”, and “−3.5 ppm”.

For example, a comparison between “−3.5 ppm” in FIG. 10A and “−3.5 ppm” in FIG. 10B demonstrates that the position of the radius exceeding |3.5 ppm| is larger in the case of FIG. 10B, where the compensation members 10 are disposed, than that in the case of FIG. 10A, where compensation members 10 are not disposed. Similarly, for example, a comparison between “−1.0 ppm” in FIG. 10A and “−1.0 ppm” in FIG. 10B demonstrates that the position of the radius exceeding |1.0 ppm| is larger in the case of FIG. 10B, where the compensation members 10 are disposed, than that in the case of FIG. 10A, where compensation members 10 are not disposed. In other words, it is indicated that an area capable of reducing fat is more improved in the case where the compensation members 10 are disposed.

As described above, in the first embodiment, the compensation members 10 formed by a substantially ring-shaped magnetic body along the circumferential direction of the substantially cylindrical shape are disposed near the center of the coil structure in the long axis direction so as to reduce the z⁴ component generated by the static field magnet 101. As a result, the z³ component generated by displacing the relative position of iron shims disposed in a space in the cylinder inner part of the gradient coil 103 can be reduced, and distortion in the uniformity of a magnetic field can be reduced. In other words, the compensation members 10 are disposed so as to reduce a higher-order-term magnetic field component. Specifically, the compensation members 10 are disposed so as to reduce a fourth-order-term magnetic field component formed by the static field magnet 101. The compensation members 10 are disposed so as to reduce a third-order-term magnetic field component generated by the movement of the gradient coil 103.

It is difficult to reduce the z³ component generated by displacing the relative position of iron shims disposed in a space in the cylinder inner part of the gradient coil 103 using active shimming. It is also difficult to reduce the z³ component using the conventional shimming with iron shims because the iron shims are displaced. Furthermore, it is difficult to reduce the z³ component using shimming in which iron pieces and the like are disposed on an end surface and the like of a static field magnet.

The above-described embodiment mainly describes reduction in third-order-term and fourth-order-term magnetic field components, but this is not limiting. For example, an effect is exerted on odd-order-term magnetic field components. Generally, odd-order-term magnetic field components, especially a first-order-term magnetic field component (z¹ component) being a low-order-term, are caused by disposing iron shims in the cylinder inner part of the gradient coil 103 asymmetrically with respect to the z-axis origin c. In the first embodiment, a part of the shimming having been originally served by iron shims in the cylinder inner part of the gradient coil 103 is served by the static field magnet 101, in other words, the compensation members 10 disposed outside the shield coil 103b. Accordingly, asymmetry of the disposition of the iron shims is eased, and a first-order-term magnetic field component is expected to be reduced. In other words, a first-order-term magnetic field component can be positively reduced by disposing the compensation members 10 so that iron shims in the cylinder inner part of the gradient coil 103 are disposed symmetrically with respect to the z-axis origin c.

### Other Embodiments

Embodiments are not limited to the above-mentioned embodiment.

Disposition of Compensation Members 10

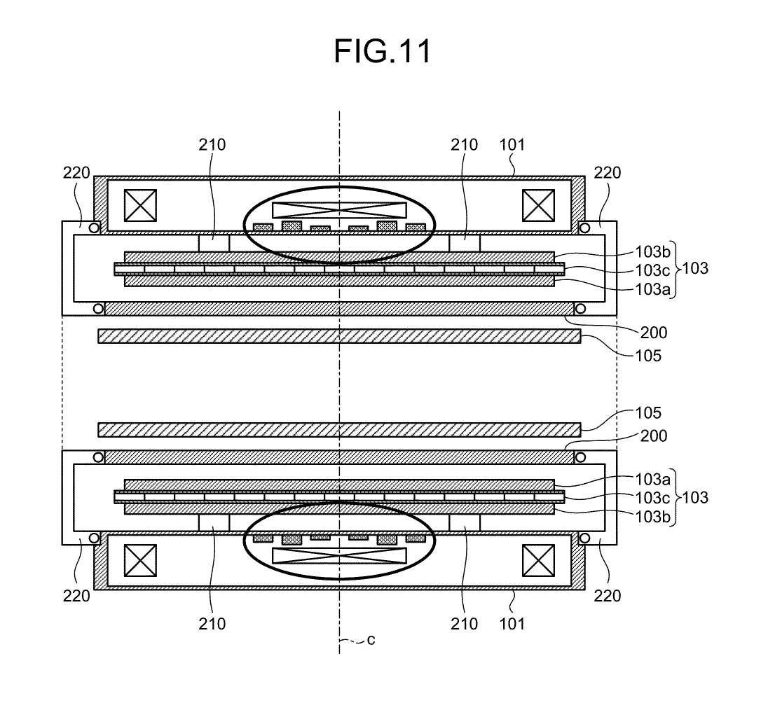

FIGS. 11 to 14 are views illustrating the disposition of the compensation members 10 according to other embodiments. FIGS. 11 to 14 illustrate the disposed positions of the compensation members 10 surrounded by circles with thick lines. The first embodiment describes an example where the compensation members 10 are disposed on the inner circumferential surface of the cylinder of the static field magnet 101, but embodiments are not limited to this. For example, as illustrated in FIG. 11, the compensation members 10 are disposed in a space in the cylinder inner part of the static field magnet 101. FIG. 11 illustrates an example where the compensation members 10 are disposed on the inner circumferential surface side in a space in the cylinder inner part, but the compensation members 10 may be disposed on the outer circumferential surface side.

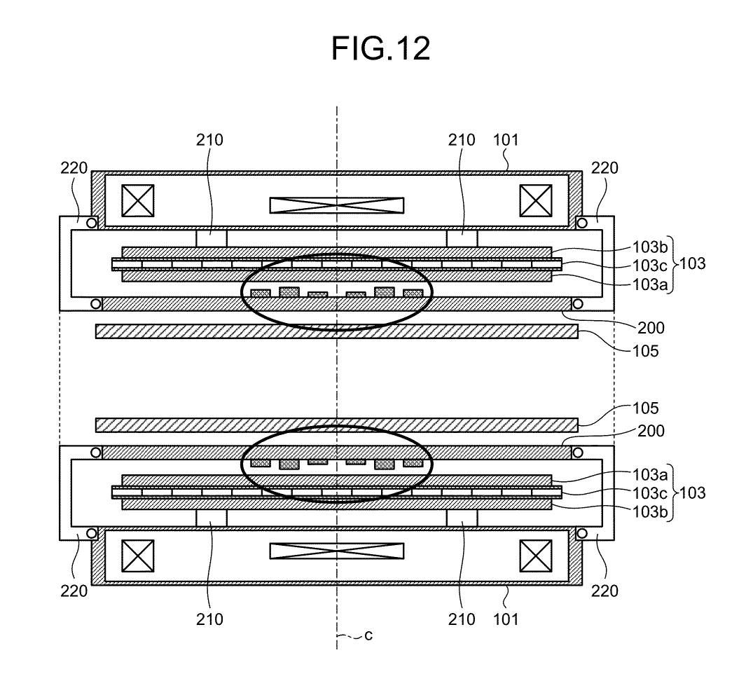

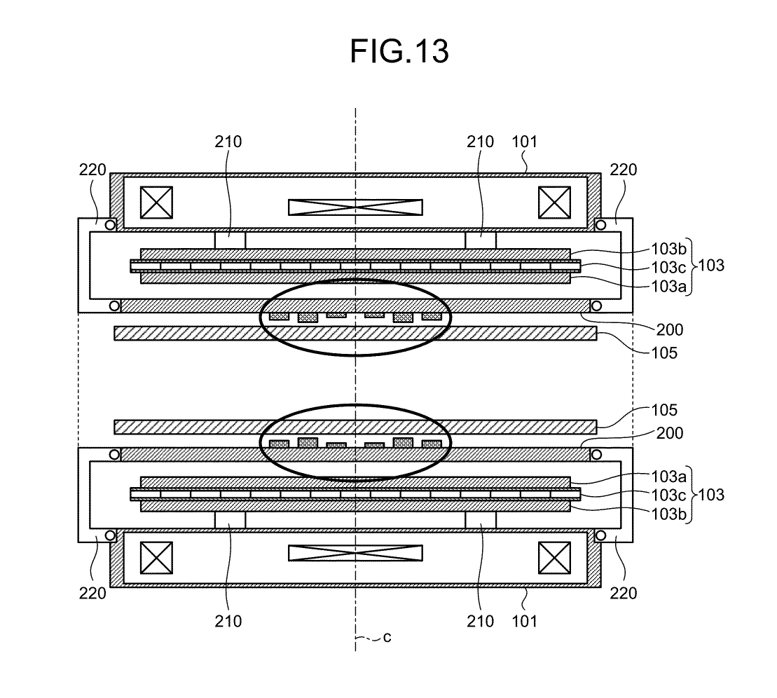

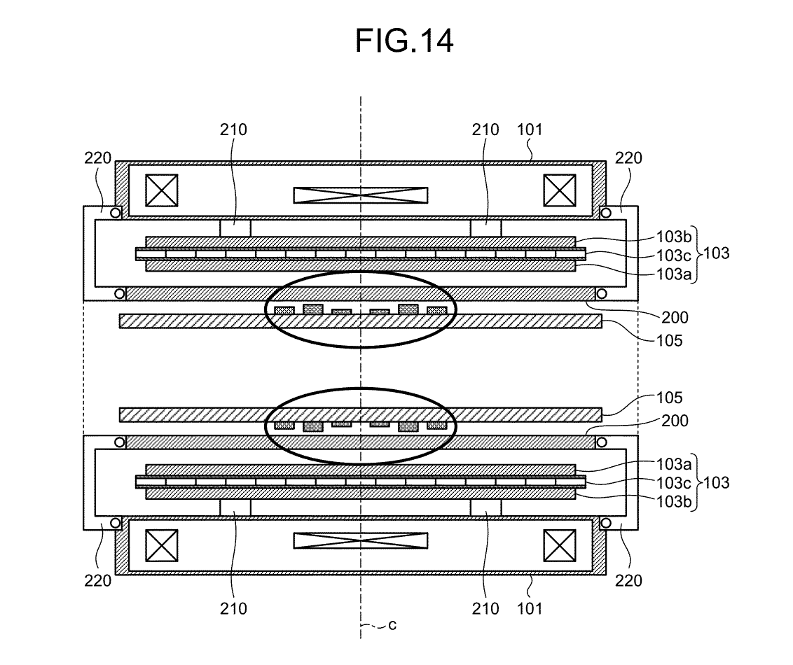

For example, the compensation members 10 may be disposed on the outer circumferential surface of the cylinder of the bore tube 200 as illustrated in FIG. 12, and may be disposed on the inner circumferential surface of the cylinder of the bore tube 200 as illustrated in FIG. 13. For example, the compensation members 10 may be disposed on the outer circumferential surface of the cylinder of the transmission coil 105 as illustrated in FIG. 14.

Other than the illustrated embodiments, the compensation members 10 can be disposed on any component that is supported substantially independently of the gradient coil 103 and keeps an original position when the gradient coil 103 is moved, such as the outer circumferential surface of the cylinder of the static field magnet 101, the inner circumferential surface of the cylinder of the transmission coil 105, and the outer circumferential surface of, the inner circumferential surface of, and a space in the inner part of the bore tube forming a living space for the subject P.

For example, when the compensation members 10 are disposed on the outer circumferential surface of the cylinder of the static field magnet 101, the thickness thereof is made thicker. In this manner, thickness and positions of the compensation members 10 are required to be changed as appropriate based on an effect corresponding to the disposed place. When welding cannot be performed, for example, when the compensation members 10 are disposed on a bore tube, some fixed member (for example, an adhesive agent) is used for disposing the compensation members 10. In this case, the bore tube and the fixed member desirably have a certain degree of strength considering that an electromagnetic force is applied to the compensation members 10 after excitation. As a timing when the compensation members 10 are disposed using a method other than welding, an installation stage at Step S2 illustrated in FIG. 9 and the like are assumed.

Combination with any Other Shimming

The method for disposing the compensation members 10 can be combined with any other shimming. The method can be appropriately combined with any other shimming, for example, with active shimming, with shimming for disposing iron shims in a space in a cylinder inner part of a gradient coil, and with shimming for disposing iron pieces and the like on an end surface and the like of a static field magnet.

The magnetic resonance imaging device according to at least one of the embodiments described above can reduce distortion in the uniformity of a magnetic field.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A magnetic resonance imaging device comprising:
a substantially cylindrical-shaped coil structure that includes a static field magnet configured to generate a magnetostatic field in a space inside a cylinder, and a gradient coil disposed inside the cylinder of the static field magnet and configured to generate a gradient magnetic field, wherein
the coil structure has a magnetic body supported independently of the gradient coil and disposed near the center of the coil structure in a long axis direction in such a way as to extend along a circumferential direction of the substantially cylindrical shape.

2. The magnetic resonance imaging device according to claim 1, wherein the magnetic body is disposed so as to reduce a higher-order-term magnetic field component.

3. The magnetic resonance imaging device according to claim 2, wherein the magnetic body is disposed so as to reduce a fourth-order-term magnetic field component formed by the static field magnet.

4. The magnetic resonance imaging device according to claim 2, wherein the magnetic body is disposed so as to reduce a third-order-term magnetic field component generated by movement of the gradient coil.

5. The magnetic resonance imaging device according to claim 1, wherein the magnetic body is disposed so as to reduce an odd-order-term magnetic field component.

6. The magnetic resonance imaging device according to claim 1, wherein the magnetic body is disposed on/in at least one of an outer circumferential surface of the cylinder of the static field magnet, an inner circumferential surface of the cylinder of the static field magnet, a space in a cylinder inner part of the static field magnet, the outer circumferential surface of a cylinder of a first bore tube for forming a sealed space with the static field magnet, an inner circumferential surface of the cylinder of the first bore tube, an outer circumferential surface of a cylinder of a radio frequency (RF) coil disposed inside the cylinder of the gradient coil, an inner circumferential surface of the cylinder of the RF coil, an outer circumferential surface of a cylinder of a second bore tube for forming a living space for a subject, and an inner circumferential surface of the cylinder of the second bore tube.

7. The magnetic resonance imaging device according to claim 1, wherein the magnetic body is disposed at a position symmetrical to the center in the long axis direction.

8. The magnetic resonance imaging device according to claim 1, wherein the magnetic body has different thicknesses corresponding to a position at which the magnetic body is disposed.

9. The magnetic resonance imaging device according to claim 1, wherein the magnetic body is silicon steel or cobalt steel.

10. The magnetic resonance imaging device according to claim 1, wherein the magnetic body includes a plurality of substantially ring-shaped magnetic body members being disposed.

11. The magnetic resonance imaging device according to claim 1, wherein the magnetic body includes a plurality of magnetic body members discretely disposed so as to form a substantially ring shape.

12. The magnetic resonance imaging device according to claim 1, wherein the magnetic body forms a ring-shaped magnetic member in the circumferential direction.

13. The magnetic resonance imaging device according to claim 10, wherein at least one of the substantially ring-shaped magnetic body members has a thickness different from that of other ring-shaped members.
